(19) United States
(12) Patent Application Publication
(10) Pub. No.: US 2012/0048366 A1
(43) Pub. Date: Mar. 1, 2012

(54) REAR JUNCTION SOLAR CELL

(75) Inventors: Ly Mai, New South Wales (AU); Matthew B. Edwards, New South Wales (AU); Martin A. Green, New South Wales (AU); Brett Hallam, New South Wales (AU); Ziv Hameiri, New South Wales (AU); Nicole B. Kuepper, New South Wales (AU); Adeline Sugianto, New South Wales (AU); Budi S. Tjahjono, New South Wales (AU); Stanley Wang, New South Wales (AU); Alison M. Wenham, New South Wales (AU); Stuart R. Wenham, New South Wales (AU)

(73) Assignee: NEWSOUTH INNOVATIONS PTY LIMITED, UNSW Sydney, New South Wales (AU)

(21) Appl. No.: 13/144,344

(22) PCT Filed: Jan. 15, 2010
(86) PCT No.: PCT/AU2010/000036

§ 371 Date: Sep. 28, 2011

(30) Foreign Application Priority Data
Jan. 16, 2009 (AU) 2009900171
Jan. 16, 2009 (AU) 2009900187

(51) Int. Cl. H01L 31/0232

(52) U.S. Cl. 136/256; 438/72; 257/E31.128

(57) ABSTRACT

A photovoltaic device is formed with a passivated light receiving first surface of a semiconductor material layer of a first dopant type. A region of oppositely doped semiconductor material is formed to create a p-n junction on at least part of a second surface located opposite to the light receiving first surface of the semiconducting material layer. First contacts are formed on the light receiving first surface of the first dopant type semiconductor material layer, and second contacts are formed on the oppositely doped material on the second surface of the semiconductor material layer.

The present invention relates to the field of solar cell manufacture and in one aspect the invention provides a method of forming a p-type doped layer in a silicon device. In another aspect the invention provides a new device structure formed on n-type silicon.

### BACKGROUND

Aluminium (Al) conductor pastes are often screen printed and spike-fired in conventional solar cell designs because it is a robust, fast and low-cost technique to produce an Al-doped p⁺ layer that acts as an effective back surface field in solar cells formed on p-type wafers. This process was developed more than 30 years ago and has been used in the commercial manufacture of screen-printed solar cells since the late 1970's. It is now proposed that the application of such screen-printed Al be used to create an alloyed p-n junction in n-type wafers, in particular, using the n⁺np⁺ solar cell structure. N-type Czochralski (CZ) wafers are reported to have significantly higher minority carrier lifetimes compared to p-type CZ wafers, and therefore, should be capable of achieving higher open circuit voltages (Voc's). However, in an n⁺np⁺ device structure on n-type CZ material, where the entire rear surface is covered by alloyed Al, Voc's of only less than 630 mV have been observed [A. Ebong, V. Upadhyaya, et al, “Rapid Thermal Processing of High Efficiency N-type Silicon Solar Cells with Al Back Junction”, Photovoltaic Energy Conversion, Conference Record of the 2006 IEEE 4^{th} World Conference], [Schmiga, C., H. Nagel, et al, “19% Efficient N-Type CZ Silicon Solar Cells with Screen-Printed Aluminium-Alloyed Rear Emitter”, Progress in Photovoltaic 14(6):533-53], therefore preventing most of the higher efficiency potential of CZ n-type wafers from being realised. This represents a severe limitation for this simple cell design.

Screen-printed aluminium paste on the rear of a silicon wafer is commonly spike-fired by heating to 750-850° C. in an infra-red belt furnace for typically less than two minutes to produce an alloyed region within which a heavily doped p-type region is formed via the epitaxial growth of aluminium doped silicon from the liquid phase. Non-uniformities however in such a layer make it difficult to form a p-n junction using this approach with n-type wafers due to such non-uniformities allowing aluminium to bypass the aluminium doped p-type region and make direct contact to the n-type wafer, usually via a Schottky barrier. Such Schottky barriers create non-linear shunting of the junction and degrade device voltages, fill-factors and currents.

When fabricating solar cells, it is also desirable to minimise both the magnitude of the processing temperature and also the process duration during thermal treatments such as diffusion processes, thermal oxidation, metal sintering etc. This is because degradation of the material quality commonly occurs during prolonged high temperature processes such as through defect generation, diffusion of contaminants into regions of the device where damage occurs, loss of hydrogen from the material etc. High temperatures for very short times (only a few seconds) or lengthy exposure to relatively low temperatures (less than 500° C.) appear not to cause significant damage. A large majority of all currently manufactured silicon wafer-based solar cells require prolonged exposure to high temperatures such as through thermal diffusions, with the potential for significant damage during such processes when using certain substrates or when in the presence of unwanted contaminants etc. Even if high performance cells can be made by such techniques, yields and repeatability tend to suffer and the cost of carrying out such processes in a suitably clean environment is high. Such techniques also tend to use much higher quantities of energy during the device fabrication.

In particular, selective emitters have been known to facilitate higher performance devices for many years. However, a large majority of such devices fabricated with selective emitters have required prolonged very high temperatures when carrying out the thermal diffusion processes to form the heavily doped regions beneath the metal contacts.

### SUMMARY OF THE INVENTION

The invention provides a method for the formation of a p-type region on a surface of silicon semiconductor material, the method comprising forming a layer of aluminium over the surface of the silicon material, spike firing the aluminium at a temperature above the aluminium-silicon eutectic temperature to form an aluminium semiconductor alloy p-type region followed by a low temperature solid phase epitaxial growth process at a temperature below the aluminium-silicon eutectic temperature whereby residual silicon within the aluminium and alloyed region form a p-type region at the aluminium/silicon interface by solid phase epitaxial growth.

This spike-firing step may be carried out at temperatures in the range of 650-950° C. and preferably 850+/−20° C. in an infra-red (IR) belt furnace. The device may only be in the furnace for a period of 5-100 seconds and typically only 2-4 seconds actually at the peak temperature.

The low temperature solid-phase epitaxial growth process may be performed at temperatures in the range of 200-577° C. and preferably at temperatures in the range of 450 to 510° C. (notionally 500° C.) for 2 to 30 minutes and typically 10+/−2 minutes at 500° C. The low temperature heating step is performed by moving the semiconductor material into an additional heating zone in infra-red belt furnaces immediately following the hottest firing zones within which the spike firing is carried out.

The Aluminium layer may be formed by screen-printing of Al paste onto the surface of the silicon material where the P+ layer is to be formed to a thickness of at least 5 micron and typically greater than 20 micron.

Preferably the silicon material is an n-type CZ wafer and the p+ layer is formed as a back layer providing a p-n junction at the non light-receiving surface of the device. The light receiving surface may be coated with an anti reflection coating and laser doped in an open grid or pattern using a phosphorous dopant source where the front side metallisation is to be formed.

The low temperature solid phase epitaxial growth process converts Schottky contacts into conventional p-n junctions, with corresponding open circuit voltage improvements as high as 70 mV having been observed in n-type solar cells with the addition of this process. The same solid-phase epitaxial growth process can be implemented and used in the formation of a conventional screen-printed rear contact and back surface field in p-type solar cells to enhance device performance by reducing the effective rear surface recombination velocity by avoiding the aluminium from contacting the lightly doped silicon wafer in localised areas. Again, improvements in open circuit voltage and current are observed, but with reduced magnitude compared to when applied to n-type wafers.

In another aspect the present invention provides a method of forming a photovoltaic device comprising,

passivating a light receiving first surface of a semiconductor material layer of a first dopant type;

forming regions of oppositely doped semiconductor material to create a p-n junction on at least part of a second surface located opposite to the light receiving first surface of the semiconducting material layer;

forming contacts to the light receiving first surface of the first dopant type semiconductor material layer; and

forming contacts to the oppositely doped material on the second surface of the semiconductor material layer.

In yet another aspect the present invention provides a photovoltaic device comprising a semiconductor body of a first dopant type having:

a passivated light receiving first surface;

regions of oppositely doped material forming a p-n junction on at least part of a second surface located opposite to the light-receiving first surface;

first metallisation contacting the light-receiving first surface of the semiconductor material layer; and

second metallisation contacting the oppositely doped regions of the second surface of the semiconductor material layer.

The method and resulting device preferably employ an n-type silicon wafer as the semiconductor material layer, however the proposed arrangement can also achieve beneficial results using a p-type wafer.

The formation of the first metallisation will typically involve laser doping through passivation or antireflection layers to increase doping level of the semiconductor areas to be contacted by the first metallisation. Laser doping may be achieved by applying a solid dopant source or supplying liquid dopant source on the surface and laser doping through surface passivation and/or anti-reflection layers. Laser doping may also involve locating the device in a gaseous dopant source atmosphere. After laser doping, self-aligned metal contacts may be applied by electroless plating, electroplating or photoplating techniques. Other metal deposition or printing techniques may also be used whereby the deposited or printed metal lines intersect the laser doped regions to facilitate electrical contact in these areas of intersection. An example of the latter is the use of semiconductor fingers produced through the use of a laser melting the silicon in the presence of a dopant source to produce the laser doped regions or lines and then subsequently screen printing metal lines so that the metal lines intersect the laser doped lines. An advantage of this approach over previous implementations of the semiconductor finger technology is that the screen-printed metal will not cause any damage to the junction if it penetrates through any surface dielectric or antireflection coating layers into the silicon in the regions away from where the laser doping has been taken place.

The light receiving first surface may also be lightly doped all over with additional dopants of the same polarity type as the wafer such as by a thermal diffusion process provided the sheet resistivity resulting from the additional dopants is not excessively low. Light receiving first surface sheet resistivities may be in the range of 100-5000 ohms per square and will preferably be in the range of 400-1000 ohms per square, where the additional doped layer is then in parallel with the sheet resistivity of the wafer itself.

Oppositely doped regions can also be formed by laser doping through surface passivation and/or anti-reflection layers. Laser doping may also involve locating the device in a gaseous dopant source atmosphere. After laser doping, self-aligned metal contacts may be applied by electroless plating, electroplating or photoplating techniques.

Where p-type regions are formed on a surface, this can be done by epitaxial growth of p+ material from a liquid silicon aluminium alloy in which case the remaining alloy can form the metallisation for the p-type region. Discontinuities in such p+ regions may be isolated from the aluminium metallisation by using solid phase epitaxy to form a further p+ region at least between the n-type material and the aluminium in the discontinuities. Where dielectric layers are employed between the semiconductor body and the aluminium metallisation, such as where rear contacts are only required intermittently over the rear surface and are formed through an dielectric layer, solid phase epitaxy may also be used to create p+ regions to isolate bridges through the dielectric layer caused by the aluminium contacting the silicon through defects such as pinholes in the dielectric layer. Solid phase epitaxy may also be used and to repair rear junction damage caused by laser doping of the light receiving surface or laser doping of the rear surface.

To avoid or minimise damage to epitaxially formed rear junctions by heat from laser doping, the laser may be operated at a pulse energy and pulse frequency which prevents the junction region reaching the eutectic temperature of Aluminium/silicon (577° C.) to thereby prevent repetitive melting and refreezing in the vicinity of the junction. Any rear junction damage caused by laser doping of the light receiving surface that might occur can also be repaired by solid phase epitaxy.

Laser doping of the light receiving surface may also be performed before the liquid phase epitaxy junction formation step.

Surface passivation can be achieved by a surface passivation layer or one of several surface treatments. An anti-reflection layer may also be provided in which case the anti-reflection layer may be applied over the surface passivation layer or surface passivation treatment. Dual layer antireflection coating may be used where the initial very thin layer is tailored for its surface passivation qualities for an undiffused silicon surface (n-type or p-type) while the second much thicker layer is optimised for its optical properties. Such dual layer coatings may be deposited in a single deposition process such as PECVD or sputtering and might comprise a thin silicon rich silicon nitride layer of refractive index above 2.0, which will typically only be in the range of 10-200 angstroms thick and the subsequent thicker coating having a thickness and refractive index selected to minimise reflection from the surface. It is also possible to use a single layer to both passivate the surface and provide the antireflection properties although usually the device performance is not as good unless an additional source of dopants is diffused into the surface being passivated as described above with sheet resistivity for the additional dopants in the range 400 to 1,000 ohms per square or above.

Contacts to the light receiving surface may comprise plated metals such as nickel, copper, tin or silver. A particular benefit of this cell design is that any of these metals can be used by itself or in combination with any of the other metals since the device junction is so far away that penetration of the metal or metals to the junction region is not a concern in the way that it is with conventional solar cell designs. For example, conventional plated metallisation schemes such as using a 10-1,000 nm thickness layer of nickel contacting the laser doped silicon followed by an overlying thicker layer of copper of thickness 1 to 30 microns could be used, or else a simplified contact involving only the use of the copper without the nickel could also be used. Such metal will usually be capped with a thin layer of tin or silver to protect the copper surface. If the laser doped semiconductor regions are formed as conductive fingers, the metal contacts can then be formed, such as by screen-printing or other suitable technique to intersect the laser doped lines or regions.

Using the proposed fabrication processes and techniques and cell design/structure embodiments may be fabricated which achieve high performance (above 19% efficiency) without the use of any processes that require the wafers to experience exposure to temperatures above 550° C. for more than 30 seconds.

### BRIEF DESCRIPTION OF THE DRAWINGS

Embodiments of the invention will now be described with reference to the accompanying drawings in which:

FIG. 1—Shows a cross-sectional SEM photo showing discontinuities in the Al-doped p⁺ layer that allows the Al to directly contact the n-type silicon of an n-type wafer after formation of an aluminium paste layer and spike firing;

FIG. 2 schematically illustrates an n-type wafer after formation of an aluminium paste layer and prior to spike firing;

FIG. 3 schematically illustrates the n-type wafer of FIG. 2 while the aluminium and some surface silicon is liquid during spike firing;

FIG. 4 schematically illustrates an n-type wafer after formation of an aluminium paste layer and spike firing;

FIG. 5 schematically illustrates the n-type wafer of FIG. 4 after further heat treatment at a lower temperature than the initial spike firing;

FIG. 6—Shows PL images illustrating an improvement in uniformity and quality of the p⁺ layer achieved by providing a low temperature treatment after a spike firing:. (a) before and (b) after the low temperature treatment;

FIGS. 7, 8 & 9 schematically show the stages in manufacture of a Photovoltaic cell using a preferred manufacturing sequence

FIG. 10 schematically illustrates a first example of a rear junction solar cell structure employing screen-printing of the rear surface with aluminium paste in the desired pattern followed by spike firing to form the rear junction and contact;

FIG. 11 schematically illustrates a second example of a rear junction solar cell structure employing laser doping of p-type dopants into the rear surface and plating the contacts;

FIGS. 12, 13 & 14 schematically show the stages in manufacture of a Photovoltaic cell using a preferred manufacturing sequence;

FIG. 15 schematically illustrates a second example of a rear junction solar cell structure illustrating use of solid phase epitaxy to overcome problems caused by defects in an oxide layer; and

FIG. 16 schematically illustrates a second example of a rear junction solar cell structure illustrating surface passivation using an electrostatic method.

### DETAILED DESCRIPTION OF EMBODIMENTS

Although it has been anticipated that an n⁺np⁺ device structure on n-type CZ material, where the entire rear surface is covered by alloyed Aluminium, should result in a high open circuit voltage (Voc), when attempting to form such devices, open circuit voltages (Voc's) of only less than 630 mV have been reported, therefore preventing most of the higher efficiency potential of CZ n-type wafers from being realised. It has been determined that discontinuities in the p⁺ layer are the main cause for this unanticipated performance degradation [A. Ebong, V. Upadhyaya, et al, “Rapid Thermal Processing of High Efficiency N-type Silicon Solar Cells with Al Back Junction”, Photovoltaic Energy Conversion, Conference Record of the 2006 IEEE 4^{th} World Conference]. The non-uniformities in such a layer, it has been determined, allow aluminium to bypass the aluminium doped p-type region, to make direct contact to the n-type wafer, usually via a Schottky barrier. Such Schottky barriers create non-linear shunting of the junction and degrade device voltages, fill-factors and currents.

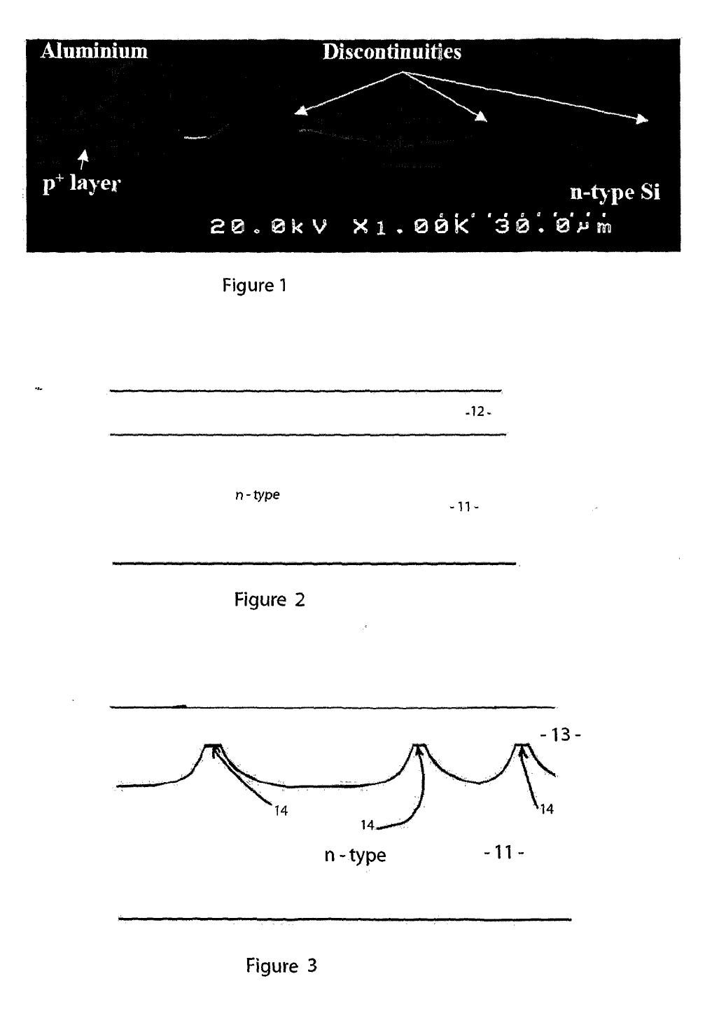

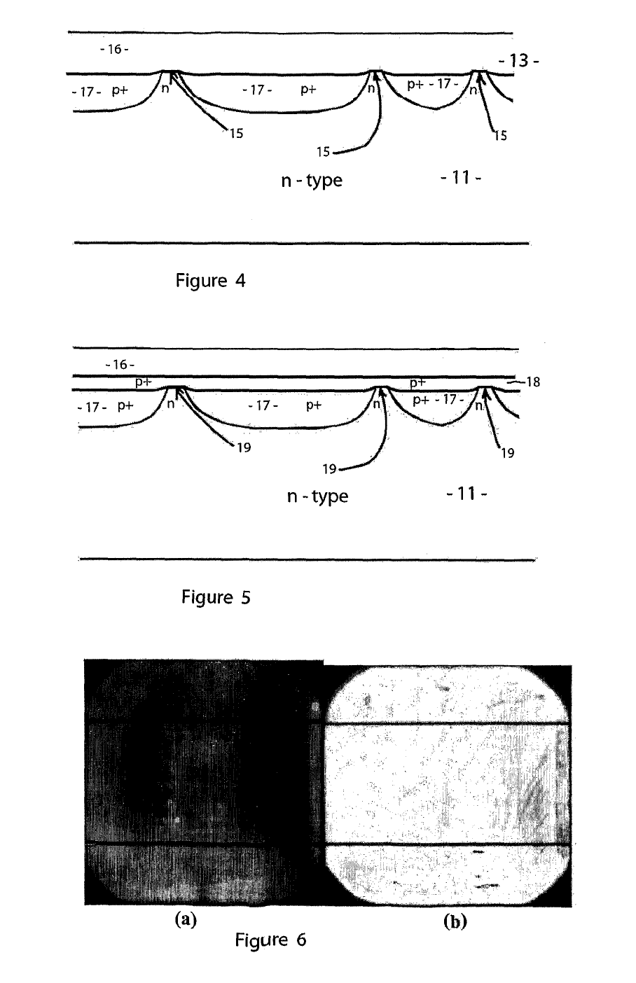

These discontinuities 15, as seen in FIGS. 1 and 4, are isolated points where the junction fails to form, apparently created by non-uniform wetting of the silicon by the Al during the alloying process. Although the presence of these discontinuities can be minimized by optimizing the firing process so as to allow more uniform wetting of the surface to occur, they cannot be completely avoided. In small quantities, such non-uniformities have almost negligible influence on the performance of the back surface field in conventional cells formed on a p-type wafer. However, they can significantly degrade the quality of Al-alloyed emitters in cells on n-type wafers by allowing Al to locally bypass the p⁺ region and directly contact the n-type bulk via a Schottky barrier causing a non-linear shunting of the junction. It is therefore proposed to use a new and modified firing process to avoid the damage from such non-uniformities by modifying the usual structure of FIGS. 1 and 4 to that of FIG. 5 through the elimination of all the shunting regions previously existing where the Al directly contacted the n-type silicon.

In the proposed method, a low temperature solid phase epitaxial growth process is employed, after the conventional standard spike firing of Al paste. Referring to FIG. 2, the process begins with the screen-printing of Al paste 12 onto the rear of an n-type silicon wafer 11 and drying at typically 300° C. During the subsequent spike-firing step, the resulting liquid Al—Si mixture 13 prior to cooling and resolidification has the form shown in FIG. 3. This spike-firing step is commonly carried out at 650-950° C. in an infra-red (IR) belt furnace for a period of typically only 2-4 seconds at the peak temperature. The conveyor belt is often run at high speeds to allow the Al to rapidly heat up and melt at above the Al—Si eutectic temperature of 577° C. The molten region 13 is then quickly cooled down and solidifies via a liquid phase epitaxial growth process of Al doped p+ silicon. This epitaxial growth process occurs on the exposed silicon surface everywhere where the silicon surface had previously been dissolved or melted through its contact with the silicon during heating. The isolated surface regions 14 shown in FIG. 3 where the Al has failed to melt the silicon, also accordingly failed to receive epitaxial growth of Al doped silicon during cooling. Therefore, the structure of FIG. 4 results following solidification with the discontinuities 15 forming where the Al failed to melt the silicon. The subsequent low temperature solid phase epitaxial growth process, performed to minimize the impact of the junction discontinuities 15 shown in FIGS. 1 and 4 will last for at typically 2 to 30 minutes and preferably for about 10 minutes.

In the liquid phase epitaxial growth process during cooling, the large majority of the Al 13 remains in the molten phase until the temperature falls below about 650° C. at which temperature the aluminium solidifies. By this stage however, the majority of the silicon from the molten layer shown in FIG. 2 has already epitaxially grown onto the exposed silicon surface to form the p+ regions 17. Consequently, once the temperature has dropped to below the Al-Silicon eutectic temperature of about 577° C. and the solidification process is complete, only a small quantity of residual silicon is left in the predominantly Al layer 16. The wafer is then deliberately held at a temperature within the range of 200-577° C. for preferably 5-20 minutes (depending on temperature) during which time the high mobility of the silicon within the Al 16 allows it to move by diffusion to exposed regions of the silicon surface where it grows onto the silicon surface by solid phase epitaxial growth to form a thin p+ layer 18. Importantly, during the 5-20 minutes of this part of the process, the highly reactive Al has sufficient time to be able to reduce or remove any interfacial oxides or residues from the regions 19 previously unaffected by contact with the Al during the short duration of the spike firing process. Consequently, negative effects of the junction shunting regions 15 from FIG. 4 where the Al directly contacts the n-type silicon are eliminated through the inclusion of a very thin solid phase epitaxial p-type layer 18 at the Al/silicon interface as shown in FIG. 5. The quality of the junction in regions where the solid phase epitaxially grown material 18 directly contacts the n-type silicon 11 is not as good a quality as the regions where the liquid phase epitaxially grown material 17 contacts the n-type silicon 11. However the presence of the former greatly improves the electrical performance compared to if the Al directly shunted to the n-type material in these regions, while the fact that the total area of such regions is still only a small percentage of the total junction area leads to minimal deterioration in performance and device voltage compared to the case of such regions not existing.

A combination of adequately thick layer of Al paste (typically in the range of 5-40 microns thick and preferably about 20 microns thick), spatially uniform high firing temperature and short firing duration during the spike firing have been shown to give a uniform and deep molten region 13 in FIG. 3 during the firing. However, junction discontinuities 15 are found to still exist in such firing schemes. In summary, due to the nature of this rapid cooling process, residual silicon is inevitably left within the Al layer 16. When subjected to temperatures in the range 200° C. to 577° C., the high mobility of the silicon within the Al allows this residual silicon to epitaxially grow onto any exposed silicon surface, including the regions of junction discontinuities 15. This solid phase epitaxially grown material 18 is Al-doped p-type, and as a result, is able to transform any localised Schottky contacts at these discontinuities where the Al directly contacts the n-type silicon, into regions 19 of good quality p-n junction. Localised shunting of the alloyed junction can therefore be avoided.

The basic solid phase epitaxy method can be used in conjunction with a range of solar cell technologies including screen-printed solar cells, buried contact (Saturn) solar cells, semiconductor finger solar cells and laser doped solar cells. It can be used with any solar cell technology for which it is feasible to incorporate screen-printed aluminium layers that are subsequently alloyed to the silicon at temperatures above 577° C. This applies regardless of whether the aluminium is used as a grid, dot, solid or some other pattern and regardless of whether the aluminium is applied to the light receiving surface or the rear of the solar cell. While the method has been described in relation to the formation of p+ layers on an n-type wafer, it is also useful for improving the performance of a p+ layer on a p-type wafer.

### Example of Devices Fabrication

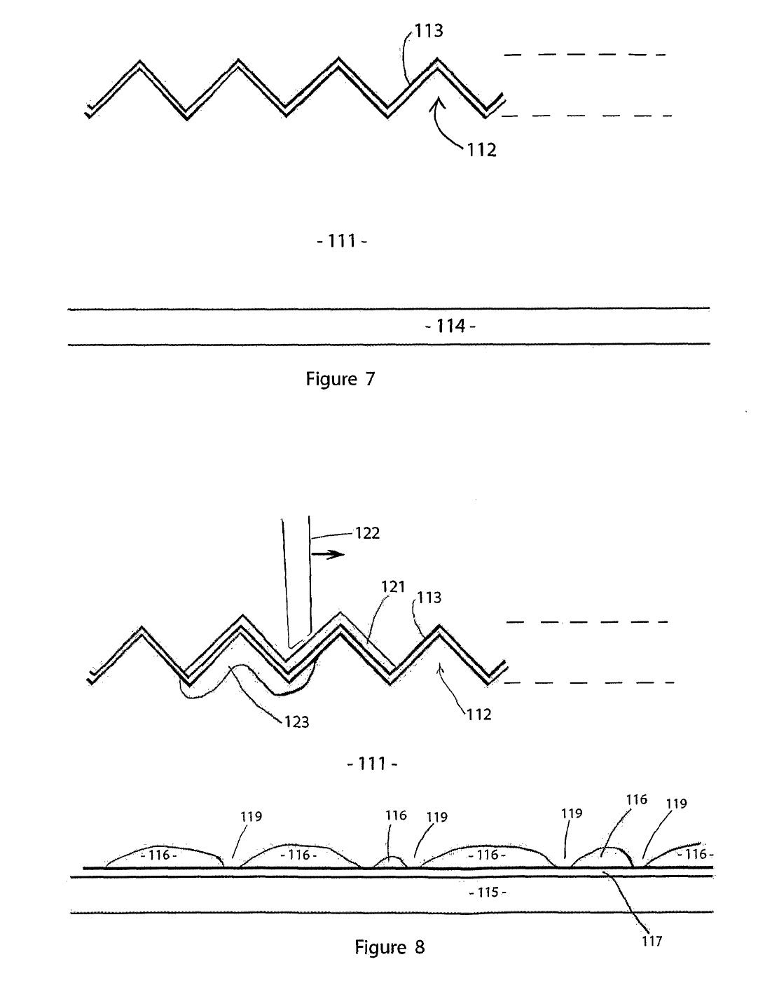

1. Referring to FIG. 7, using 180 μm thick, industrial type 5″, 2.5 ohm-cm CZ n-type wafers 111;
2. Alkaline texturing to form upright random pyramids 112 on the light receiving surface (these may also form on the rear surface);
3. Deposition of a 75 nm thick silicon nitride layer 113 on the light receiving wafer surface;
4. Screen-printing a 20 micron layer of Al 114 onto the rear surface of the wafer 111 followed by conventional spike firing process in an infra-red belt furnace to form an Al—Si alloy layer 115 and p+ regions 116 shown in FIG. 8.
5. Heat wafer to 500° C. for 10 minutes in a nitrogen ambient (although air ambient or almost any other ambient is also acceptable) to form a thin p+ layer 117 which separates the Al—Si layer 115 from the bulk of the n-type substrate at the discontinuities 119.
6. Application of phosphorus source 121 to the light receiving surface Note the dopant source may be solid, liquid or gaseous but is shown as a solid deposition for ease of drawing.
7. Heating the source with a laser 122 to produce heavily phosphorus doped silicon 123 everywhere the metal grid is to be located.
8. Referring to FIG. 9, electrodes 124 are formed by Ni/Cu/Ag plating on the light receiving surface including sintering of the Ni following its application;

The application of the described method employing the new low temperature firing process appears to not only make the variation in Voc across a wafer smaller but also improve the absolute value of the open circuit voltages very significantly to at least 650 mV compared to if only the conventional spike firing of the Al screen-printed contact is used. FIG. 6 shows photoluminescent images of a wafer before and after the application of the solid phase epitaxial growth step. FIG. 6(a) shows a device in which only the conventional spike firing of the Al screen-printed contact is used, while FIG. 6(b) shows the improved response and uniformity resulting from the application of the solid phase epitaxial growth process described herein.

A variation of the method can be achieved by deliberately modifying the spike firing conditions to retain additional residual silicon within the Al layer such as by rapid freezing of the molten region leaving insufficient time for some of the liquid phase epitaxial growth process to take place. One method of rapid cooling is to blow cool air onto the wafer as it departs from the firing zone of the furnace. This makes additional silicon available for the subsequent solid phase epitaxial growth process. This is the opposite to what the industry has done for 30 years, which is to do the spike firing so as to minimise the amount of residual silicon in the Al as excessive silicon has detrimental effects on the electrical conductivity of the Al while simultaneously resulting in the formation of a thinner p+ layer between the Al and the silicon wafer. If considered beneficial, the spike firing can be followed by an additional deposition of silicon such as by sputtering, E-beam evaporation or PECVD onto the rear surface prior to heating the wafer to about 500° C. This provides additional silicon for the solid phase epitaxial growth process since on heating, the additional Silicon rapidly penetrates into the Al layer.

Solar cell embodiments based on n-type wafers will now be described to illustrate further aspects of the invention but it will be recognised that the main principles of the following proposed method and structure can be applied to p-type wafers as well.

In general, most solar cells currently manufactured commercially are built on a p-type material and require a high temperature thermal diffusion of phosphorus into the top surface of the material so as to provide adequate lateral conductivity for the generated charge carriers to travel to the closest metal fingers and also to provide adequately high doping concentrations for the top surface metallisation to make good ohmic contact to the crystalline silicon.

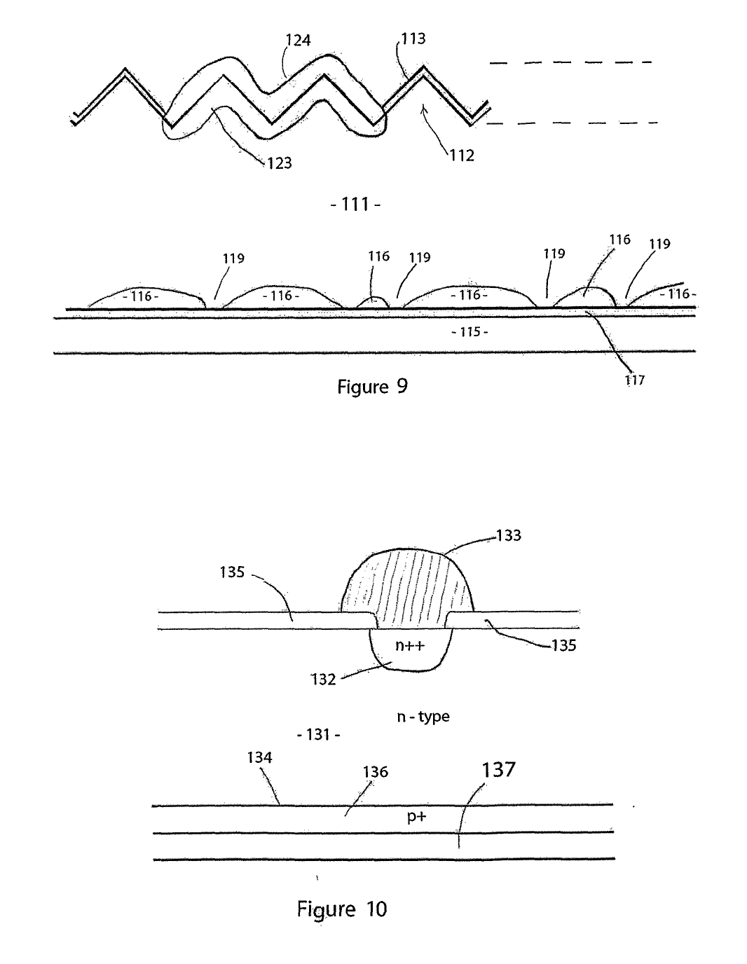

Referring to FIG. 10, the proposed method and structure alleviate the need for the diffusion of phosphorus dopants into the top surface of the type wafer by choosing a phosphorus doped wafer. The n-type silicon wafer 131 will be chosen to be of the right resistivity to give the lateral conductivity necessary for collected/generated electrons to travel laterally to the doped regions 132 located under the metal contacts 133 without excessive resistive losses. This is believed to be a unique feature of the presently disclosed arrangement with little or no top surface diffusion required apart for under the metallisation. The junction 134 however is particularly deep, being located near the rear of the device. Consequently the top surface passivation is particularly important in this structure to reduce the surface recombination velocity to adequately low values to facilitate collection of the generated holes at the rear junction. Various approaches for forming the anti-reflection coating while simultaneously achieving adequate top surface passivation have been demonstrated and reported in the literature such as by PECVD deposition of a silicon nitride layer 135.

The equivalent of a selective emitter 132, with heavy doping beneath the metal and light doping elsewhere on the surface, may be formed by the laser doping of localised areas of the silicon wafer 131 with phosphorus. This avoids subjecting the wafer to high temperatures above 500° C. for more 30 seconds. The metal contacts 133 are subsequently self-aligned to these heavily doped regions 132 such as via electroless plating, electroplating or photoplating techniques.

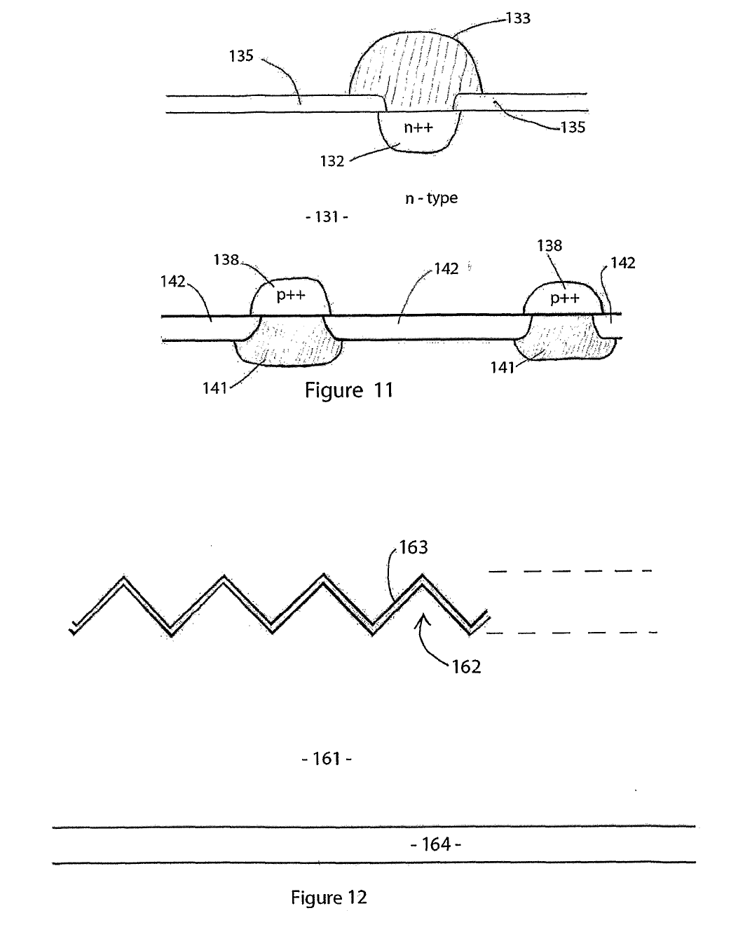

In this device design, the rear junction can be formed by various approaches of forming a rear p-type region that still avoids subjecting the wafer to temperatures above about 500° C. for more than about 30 seconds. There are two preferred approaches for forming the rear junction and contact(s). A first approach involves screen-printing the rear surface with aluminium paste in the desired pattern followed by spike firing at typically 750-850° C. for about 30 seconds to produce a p₊ region 136 of silicon doped with aluminium at about 2×10¹⁸ atoms/cm³ and a layer of residual aluminium (retaining some dissolved silicon) 137, such as is shown in FIG. 10. Alternatively, laser doping may be used to diffuse p-type dopants into the rear surface through a dielectric layer 142, so as to produce p+ doped regions 138 in a pattern of localised areas (e.g. a grid pattern or other pattern) such as is shown in FIG. 11. The metal contacts 141 are subsequently self-aligned to these heavily doped regions 138 such as via electroless plating, electroplating or photoplating techniques or other metallisation techniques such as described earlier for the light receiving surface.

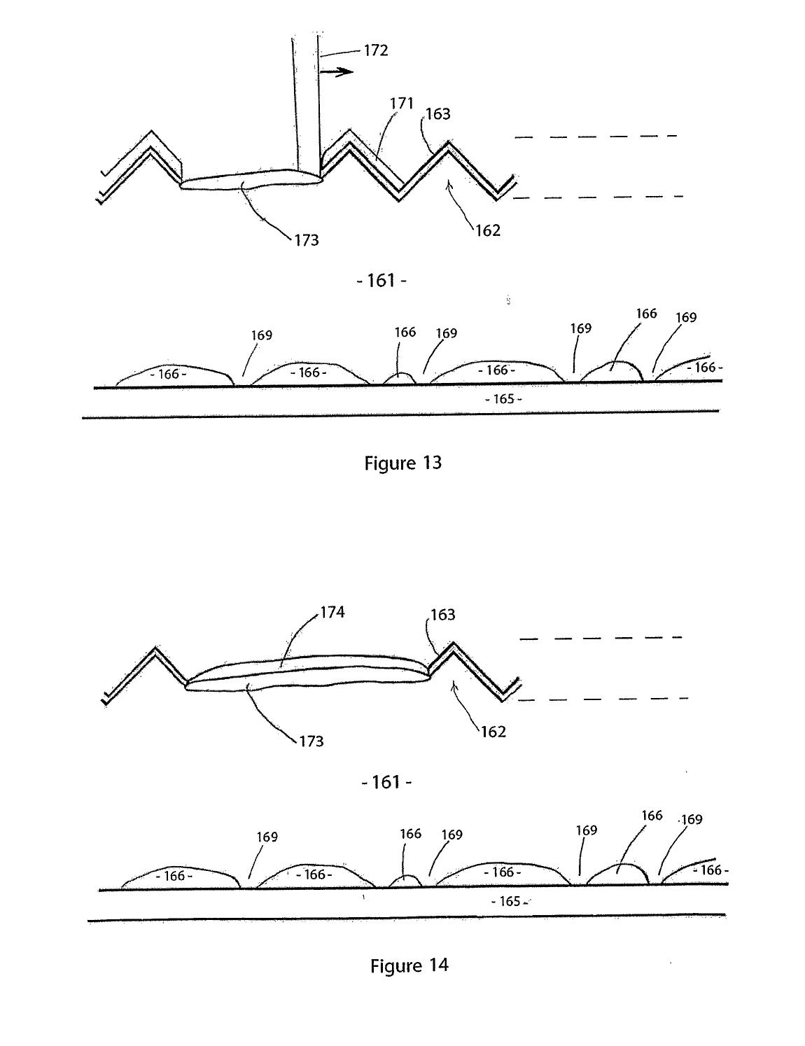

Referring to FIGS. 12, 13 and 14, an example of possible implementation steps which will lead to the cell design of FIG. 10 is as follows:
1. Referring to FIG. 12, using 180 μm thick, industrial type 5″, 2.5 ohm-cm CZ n-type wafers 161;
2. Alkaline texturing to form upright random pyramids 162 on the light receiving surface;
3. Deposition of a 75 nm thick silicon nitride layer 163 on the light receiving wafer surface;
4. Screen-printing approx 20 micron layer of Al 164 onto the rear surface of the wafer 161 followed by conventional spike firing process in an infra-red belt furnace to form an Al—Si alloy layer 165 and p+ regions 166 shown in FIG. 13.
5. Application of phosphorus source 171 to the light receiving surface. Note the dopant source may be solid, liquid or gaseous but is shown as a solid deposition for ease of drawing.
6. Heating the dopant source with a laser 172 to produce heavily phosphorus doped silicon 173 everywhere the metal grid is to be located.
7. Referring to FIG. 14, electrodes 174 are formed by Cu/Ag or Ni/Cu/Ag plating on the light receiving surface including sintering of the Ni following its application;

In general the preferred scheme for electrode metallisation 174 in laser doped cells is initially a thin layer of nickel followed by a much thicker layer of copper followed by a very thin layer of either silver or tin. The copper is intended to be the main electrical conductor, but requires the nickel as an interface layer to the silicon which when sintered at about 400° C. forms nickel silicide which acts as a diffusion barrier to prevent the diffusion of copper into the silicon into the junction region which is typically only about 1 micron away from the surface. An important and unique aspect of this cell design is that in step 7 above, the nickel is no longer required as an interface layer to the silicon since the copper on the front surface is displaced from the junction by a long distance approximately equal to the width of the wafer. Alternatively, the nickel could still be included but not sintered until the end when the complete metallisation scheme has been formed. This is acceptable since there is no longer a concern with this cell fabrication sequence about heating the wafer to 400° C. when there is copper already plated onto the surface.

In the case of implementing the cell design of FIG. 10 with the aluminium rear, if the laser doping of the front surface is done after firing the aluminium, the heat from the laser can potentially damage the quality of the rear p+ region in close proximity since the Eutectic temperature for aluminium and silicon is only 577° C. This problem can be solved in three ways.

Firstly, if the laser pulses for melting and doping the silicon are kept sufficiently short with the pulse energy below a certain critical level, the silicon can be melted at the front of the wafer while the rear surface remains below 577° C., the eutectic temperature for aluminium and silicon at which the rear junction region begins melting. If such melting is to occur, the existing high quality p+ region formed during the epitaxial growth process that took place during the spike firing of the aluminium will be damaged due to the rapid freezing that follows the laser pulse. If suitably short pulses are used to avoid this melting of the rear junction, many laser pulses are required in each location so as to melt the silicon for long enough to allow adequate mixing of the dopants as taught by Wenham and Hameiri in Provisional Patent Application Number 2009900924 Improved laser operation for localised doping of silicon. If these pulses are more than a microsecond or so apart, the silicon at the front surface refreezes between pulses, allowing the rear junction region to also cool sufficiently so that multiple pulses of this type will not cause significant damage to the junction or p+ regions. In this same Patent Application by Wenham and Hameiri, it is taught that many pulses in the same location can cause considerable damage due to defects formed in adjacent regions to the laser doped region due to the thermal expansion mismatch between the silicon and the overlying anti-reflection coating. Such defects cause degradation in device performance, primarily because of their impact either on the junction region or else in bypassing the junction through shunting. These problems are avoided in the presently described structure by locating the junction well away from the laser doped regions so that such defects cannot cause either junction recombination or junction shunting.

Secondly, problems with the laser damaging the rear junction/p+ region can be overcome by carrying out a solid-phase epitaxial growth process at a temperature of typically 400-500° C. following the laser doping process so as to repair the damage. If the laser pulses at the front surface are able to melt the silicon/aluminium/p+ regions at the rear, rapid freezing at the end of each pulse prevents the formation of a good quality epitaxially grown P+ layer and corresponding good quality junction. The rapid freezing however leaves residual silicon within the aluminium layer. At temperatures in the range of 200 to 577° C., this residual silicon will epitaxially grow onto the crystalline silicon surface, doped with aluminium at about 2×10¹⁸ atoms/cm³. This can be used to isolate the aluminium from any exposed n-type regions, thereby repairing damage such as through shunting created by the heat from the laser during the laser doping process at the front of the wafer.

Thirdly, the described problems with the damage to the rear junction by the laser doping process at the front of the wafer, can be overcome by reversing the order and carrying out the laser doping process prior to applying the screen-printed aluminium contact. In this way, heat from the laser is unable to damage the junction. However, the spike firing does in turn cause some complications to the laser doped regions such as oxidation of the surface that therefore requires additional processing later in preparation for the plating processes.

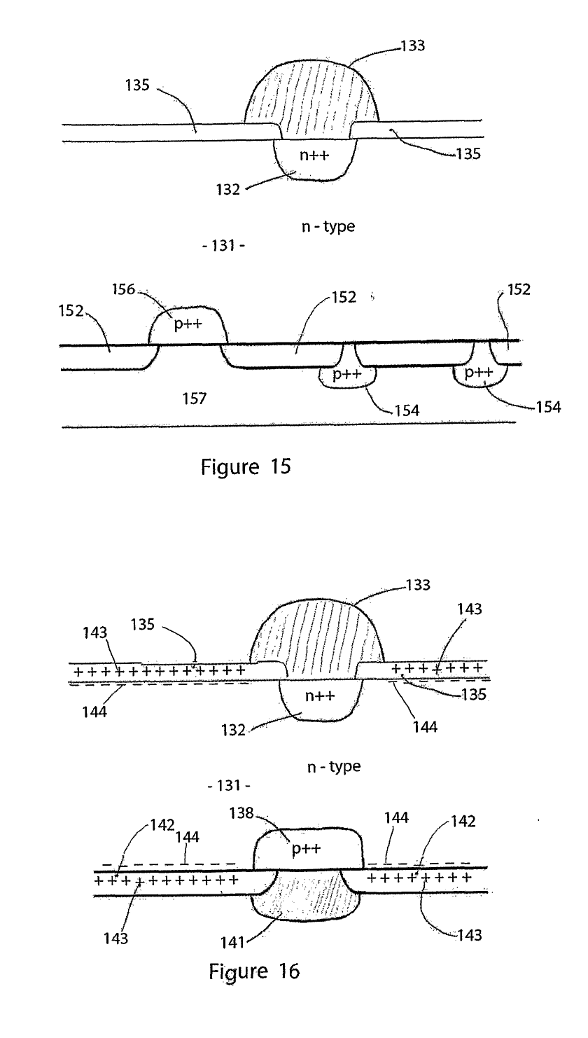

In the case where laser doped regions are used on the rear surface as illustrated in FIG. 15, silicon nitride 152 (or other surface passivating dielectric layer) is first deposited onto the rear to passivate the surface of the n-type wafer 131. A valency 3 dopant source is either incorporated into the silicon nitride layer 152 or else subsequently applied to the rear surface followed by laser doping in a similar fashion to on the front with the phosphorus source. Following the laser doping of localised areas 156 of the rear, aluminium layer 157, preferably containing a small concentration of silicon (or the silicon can be subsequently deposited onto the aluminium layer), can be deposited onto the rear prior to carrying out the solid phase epitaxial growth process. This solid phase epitaxial growth process is particularly important for damage and defects created adjacent to the laser melted regions 156 on the rear by the thermal expansion coefficient mismatch between the silicon nitride 157 and the silicon wafer 131. Any damage to the silicon nitride 157 such as the openings 153 (e.g. pin holes) will result in exposed regions of silicon which will normally lead to shunting of the junction when the aluminium is deposited. In this case however, the high mobility of the silicon within the aluminium 157 allows the silicon to rapidly epitaxially grow onto any exposed silicon regions that may have resulted from such defects or damage from the laser doping process on the rear. This solid phase epitaxially grown material 154 is doped p-type by the aluminium and therefore repairs any damage or shunting of the junction. Similarly, any pinholes in the silicon nitride 152 which would allow the aluminium to directly contact the n-type surface therefore causing shunting, will also nucleate solid phase epitaxial growth of p-type material in such pinhole locations, therefore forming a localised junction that will prevent shunting or the formation of unwanted Schottky contacts. An example of possible implementation steps which will lead to the cell design of FIG. 15 is as follows:
1. Texture surfaces of n-type wafer
2. silicon nitride deposition onto both front and rear surfaces
3. Application of n-type dopant source onto the front surface
4. Application of p-type dopant source onto the rear surface
5. Laser doping of both front and rear surfaces
6. Deposition of Al containing a few percent silicon such as by sputtering, plasma spraying, E-beam, thermal evaporation or screen-printing, onto the wafer rear
7. 10 minute heat treatment at 500° C. to facilitate solid phase epitaxial growth (and simultaneously sinter the Al onto the Si)
8. Plating of front metal contact

In this described implementation of the FIG. 15 cell design, it is possible to avoid the use of the aluminium and the subsequent solid phase epitaxial growth process, provided the laser doping at the rear can be carried out in a manner that avoids problems from defect generation or other damage adjacent to the laser melted regions. In this case for example, plated contacts 141 could be used to contact the p-type laser doped regions as shown in FIG. 11. An example of possible implementation steps which will lead to the cell design of FIG. 11 is as follows:
1. Texture surfaces of n-type wafer
2. silicon nitride deposition onto both front and rear surfaces
3. Application of n-type dopant source onto the front surface
4. Application of p-type dopant source onto the rear surface
5. Laser doping of both front and rear surfaces
6. Plating of front and rear metal contacts (including sintering of the nickel prior to deposition of the copper and silver or tin)

Another important aspect of this fabrication sequence is the deposition of the silicon nitride layer in a way that allows it to act as a plating mask for the formation of the metal electrodes such as through photoplating. Diffused surfaces in general interfere with the PECVD deposition process for silicon nitride, leading to the formation of pinholes that subsequently interfere with the plating processes leading to unwanted plating in the vicinity of the pinholes. Avoiding the use of diffused surfaces in this fabrication sequence therefore avoids this problem of pinholes in the silicon nitride layer.

Another important aspect of this proposed technique is the quality of surface passivation achievable with the undiffused top surface. The best results have been achieved with a multilayer antireflection coating whereby the first layer is very thin and deposited specifically for its surface passivation qualities. An example is a silicon rich silicon nitride layer of refractive index above 2.0, which will typically only be in the range of 10-200 angstroms thickness to avoid excessive light absorption. In this case, the second layer deposited onto the first layer needs to be much thicker than the first layer and of thickness and refractive index to minimise the reflection from the surface.

A variation of the above would be to either lightly diffuse the surfaces with phosphorus to reduce surface recombination or else deliberately incorporate positive charge 143 into the dielectric layer so as to increase the negative charge 144 at the surface of the semiconductor electrostatically as shown in FIG. 16 to also reduce the surface recombination. A surface n-type layer having a sheet resistivity of 500 ohms per square or above would be adequate for these purposes, but would only be needed if the direct surface passivation of the silicon by the dielectric layer is inadequate.

While embodiments described herein have been presented from the perspective of using n-type wafers, exact equivalents could be implemented for the use of p-type wafers. Also, when opposite polarity dopant sources are applied to the front and rear surfaces prior to laser doping, depending on the sources used, one polarity may need to be done at a time with that source then removed prior to the application of the opposite polarity source on the opposite surface to prevent the two polarities from interfering with each other.

It will therefore be appreciated by persons skilled in the art that numerous variations and/or modifications may be made to the invention as shown in the specific embodiments without departing from the scope of the invention as broadly described. The present embodiments are, therefore, to be considered in all respects as illustrative and not restrictive.

1-58. (canceled)

59. A method of forming a photovoltaic device, comprising;
a) passivating a light receiving first surface of a semiconductor material layer of a first dopant type;
b) forming a region of oppositely doped semiconductor material on at least part of a second surface located opposite to the light receiving first surface of the semiconducting material layer to create a p-n junction adjacent to the second surface;
c) applying a dopant source adjacent to the light receiving surface of the same dopant type as the semiconductor material;
d) laser doping the light receiving surface of the semiconductor material through the dopant source to increase a doping level of semiconductor areas to be contacted by a first metal contact to the light receiving first surface of the semiconductor material, wherein the laser doping step causes surface melting of the semiconductor areas to be contacted by the first metal contact.
c) forming the first metal contacts to the laser doped areas of the light receiving first surface of the first dopant type semiconductor material layer; and
d) forming second contacts to the oppositely doped material on the second surface of the semiconductor material layer.

60. The method of claim 59 wherein a passivation layer or surface passivation treatment provides the surface passivation.

61. The method of claim 59 wherein an antireflection layer is formed over the light receiving first surface and also provides the surface passivation and the formation of metal contacts to the light receiving first surface of the first dopant type comprises laser doping through the antireflection layer.

62. The method of claim 59 wherein an antireflection layer is formed over the light receiving first surface and the formation of metal contacts to the light receiving first surface of the first dopant type comprises laser doping through the antireflection layer.

63. The method of claim 59 wherein the laser doping comprises applying a solid dopant source to the light receiving first surface or supplying a liquid dopant source to the light receiving first surface, or locating the light receiving first surface of the device in a gaseous dopant source atmosphere, and laser doping through surface passivation or anti-reflection layers.

64. The method of claim 63 wherein after laser doping, self-aligned metal contacts are applied by one of an electroless plating, electroplating or photoplating technique.

65. The method as claimed claim 59 wherein semiconductor material adjacent to the light receiving first surface is lightly doped all over with additional dopants of the first dopant polarity.

66. The method as claimed in claim 65 wherein the doping of the light receiving surface is preformed using a thermal diffusion process.

67. The method as claimed in claim 59 wherein the semiconductor material layer comprises an n-type crystalline silicon wafer and the oppositely doped region is a p-type regions formed by laser doping through the surface passivation, the oppositely doped region being formed by applying a solid dopant source to the second surface opposite the light receiving first surface or supplying a liquid dopant source to the second surface opposite the light receiving first surface, or locating the second surface opposite the light receiving first surface of the device in a gaseous dopant source atmosphere, and laser doping the second surface of the device.

68. The method as claimed in claim 59 wherein the semiconductor material layer comprises an n-type crystalline silicon wafer and the oppositely doped region is a p-type region formed by epitaxial growth of p+ material from a liquid silicon aluminium alloy.

69. The method as claimed in claim 68 wherein a remainder of the liquid silicon aluminium alloy forms an aluminium metallisation for the p-type region.

70. The method as claimed in claim 59 wherein the laser is operated at a pulse energy and pulse frequency which prevents the junction region reaching the eutectic temperature of aluminium/silicon.

71. The method as claimed in claim 59 wherein contacts to the light receiving surface comprise plated metals selected from one or more of nickel, copper, tin or silver.

72. A photovoltaic device comprising a semiconductor body of a first dopant type having:
a passivated light receiving first surface;
a region of oppositely doped material on at least part of a second surface located opposite to the light-receiving first surface, forming a p-n junction adjacent to the second surface;
first metallisation contacting the light-receiving first surface of the semiconductor material layer;
semiconductor regions of the first surface of the semiconductor body under the first metalisation which are more heavily doped than the remainder of the first surface of the semiconductor body and of the same dopant type as the semiconductor body, whereby the first metalisation contacts the more heavily doped regions and is isolated from undoped regions of the first surface of the semiconductor body; and
second metallisation contacting the oppositely doped regions of the second surface of the semiconductor material layer.

73. The photovoltaic device as claimed in claim 72 wherein semiconductor material adjacent to the light receiving first surface is lightly doped all over with additional dopants of the first dopant polarity.

74. The photovoltaic device as claimed in claim 72 wherein an antireflection layer extends over the light-receiving first surface and the first metallisation extends through the antireflection layer.

75. The photovoltaic device as claimed in claim 72 wherein the semiconductor body comprises an n-type crystalline silicon wafer and the oppositely doped region is a p-type crystalline silicon region doped with aluminium.

76. The photovoltaic device as claimed in claim 75 wherein a silicon aluminium alloy forms an aluminium metallisation for the p-type region.

77. The photovoltaic device as claimed in claim 72 wherein contacts to the light receiving surface comprise plated metals selected from one or more of nickel, copper, tin or silver.
